(19) United States
(12) Patent Application Publication
(10) Pub. No.: US 2024/0184946 A1
(43) Pub. Date: Jun. 6, 2024

(54) RESERVOIR SIMULATION DATA QUALITY ASSURANCE

(71) Applicant: SAUDI ARABIAN OIL COMPANY, Dhahran (SA)

(72) Inventors: Jibran AYUB, Dhahran (SA); Raheel R. BAIG, Dhahran (SA)

(73) Assignee: SAUDI ARABIAN OIL COMPANY, Dhahran (SA)

(21) Appl. No.: 18/060,792

(22) Filed: Dec. 1, 2022

(51) Int. Cl. G06F 30/20

(52) U.S. Cl. CPC G06F 30/20

(57) ABSTRACT

One or more embodiments described herein can relate to systems and methods for automatically performing one or more well trajectory data consistency checks and/or well perforation event consistency checks. For example, one or more embodiments can include a system that can comprise memory to store computer executable instructions. The system can also comprise one or more processors, operatively coupled to the memory, that execute the computer executable instructions to implement a well trajectory evaluator configured to validate well trajectory data for a subsurface reservoir simulation model by comparing a difference between sets of deviation survey data to a defined trajectory tolerance. The one or more processors can also execute the computer executable instructions to implement a perforation event analyzer configured to validate well attribute data for the subsurface reservoir simulation model via conditional logic that analyzes the position of a perforation event along a well trajectory in relation to a targeted geographical zone.

### FIELD OF THE DISCLOSURE

The present disclosure relates generally to assuring the data quality for simulations that model subsurface reservoirs and, more particularly, to systems and/or methods for evaluating the well trajectory data and perforation event data employed by a subsurface reservoir simulation model.

### BACKGROUND OF THE DISCLOSURE

During the production life cycle of oil and gas extraction from a hydrocarbon reservoir field, subsurface reservoir simulation models are constructed to predict gas and/or oil production. To construct these models, raw data regarding the reservoir, and wells proposed for accessing the reservoir, are integrated and interpreted by a reservoir simulation engineer. Said data can characterize various geological features of the reservoir along with field development plans for the wells.

Thus, the subsurface reservoir simulation model can be the product of a vast amount of complex geological and/or engineering input data, which has to be quality controlled and cross-checked to eliminate inconsistencies during later phases of development. Traditionally, data quality assurance is performed by manual operations, which are time intensive and rely on the expertise of subject matter experts.

### SUMMARY OF THE DISCLOSURE

Various details of the present disclosure are hereinafter summarized to provide a basic understanding. This summary is not an extensive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

According to an embodiment consistent with the present disclosure, a system is provided. The system can comprise memory to store computer executable instructions. The system can also comprise one or more processors, operatively coupled to the memory, that execute the computer executable instructions to implement a well trajectory evaluator configured to validate well trajectory data for a subsurface reservoir simulation model by comparing a difference between sets of deviation survey data to a defined trajectory tolerance. The one or more processors can also execute the computer executable instructions to implement a perforation event analyzer configured to validate well attribute data for the subsurface reservoir simulation model via conditional logic that analyzes the position of a perforation event along a well trajectory in relation to a targeted geographical zone.

In another embodiment, a method is provided. The method can comprise validating well trajectory data for a subsurface reservoir simulation model by comparing a difference between sets of deviation survey data to a defined trajectory tolerance. Also, the method can comprise validating well attribute data for the subsurface reservoir simulation model via conditional logic that analyzes the position of a perforation event along a well trajectory in relation to a targeted geographical zone.

In a further embodiment, a computer program product for performing a well trajectory data consistency check and a perforation event consistency check is provided. The computer program product can comprise a computer readable storage medium having computer executable instructions embodied therewith. The computer executable instructions can be executable by one or more processors to cause the one or more processors to validate well trajectory data for a subsurface reservoir simulation model by comparing a difference between sets of deviation survey data to a defined trajectory tolerance. Additionally, the computer executable instructions can cause the one or more processors to validate well attribute data for the subsurface reservoir simulation model via conditional logic that analyzes the position of a perforation event along a well trajectory in relation to a targeted geographical zone.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is a non-limiting example system that can evaluate the trajectory and/or perforation event configuration of one or more wells of subsurface reservoir simulation model based on deviation survey data in accordance with one or more embodiments described herein.

FIG. 2 is a non-limiting example system that can evaluate the consistency of deviation survey data characterizing the trajectory of one or more wells in a subsurface reservoir simulation model in accordance with one or more embodiments described herein.

FIG. 3A-3B illustrate non-limiting example well trajectory errors that can result from inconsistencies within the deviation survey data employed by a subsurface reservoir simulation model in accordance with one or more embodiments described herein.

FIG. 4 illustrates a non-limiting example flow diagram of computer-implemented method that can be employed by one or more systems to evaluate the trajectory of one or more wells modeled by a subsurface reservoir simulation in accordance with one or more embodiments described herein.

FIG. 5 is a non-limiting example system that can evaluate the accuracy of one or more perforation events of one or more wells in a subsurface reservoir simulation model in accordance with one or more embodiments described herein.

FIG. 6 illustrates a portion of a non-limiting example subsurface reservoir simulation that can be analyzed by a zone logger to map portions of a well's trajectory to geographical zones of interest in accordance with one or more embodiments described herein.

FIG. 7 illustrates a non-limiting example of various correction operations that can be employed by the system to achieve a desired perforation event configuration for one or more wells modeled by a subsurface reservoir simulation in accordance with one or more embodiments described herein.

FIG. 8 illustrates a non-limiting example flow diagram of computer-implemented method that can be employed by one or more systems to analyze the perf events of one or more wells modeled by a subsurface reservoir simulation in accordance with one or more embodiments described herein.

FIG. 9 illustrate a non-limiting example of multiple perforation events that can be associated with one or more wells modeled by a subsurface reservoir simulation in accordance with one or more embodiments described herein.

FIG. 10 illustrates a block diagram of non-limiting example computer environment that can be implemented within one or more systems described herein.

### DETAILED DESCRIPTION

Embodiments of the present disclosure will now be described in detail with reference to the accompanying figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments in accordance with the present disclosure generally relate to systems and/or computer-implemented methods that can automatically perform various data consistency checks to assess the quality of input data used to generate subsurface reservoir models. One or more embodiments described herein comprises evaluating data consistency amongst multiple sets of deviation survey data received from multiple data sources. For example, well trajectory data can be cross-checked against multiple data sources to ensure data consistency. Additionally, the well trajectory data can be analyzed to detect trajectory distortions. For example, the data consistency checks can be performed prior to exporting well trajectory data to a simulation engine for generating the subsurface reservoir models.

Further, various embodiments described herein comprise analyzing the perforation events of wells modeled by the subsurface reservoir simulations. For example, perforation events can be evaluated in relation to targeted geological zones to ensure that the wells are in fluid communication with desired portions of the subsurface reservoir. The perforation events can be evaluated utilizing conditional logic protocols based on the measured depth of the top and bottom points of the perforation event along the well's trajectory. In some embodiments, the systems and/or computer-implemented methods can automatically execute one or more correction operations to remedy erroneous portions of the perforation events (e.g., where portions of the perforation events extend beyond the targeted geological zones). For example, the perforation event consistency checks can be performed prior to exporting well attribute data to a simulation engine for generating the subsurface reservoir models.

Moreover, one or more embodiments described herein can include the generation of data consistency reports to aid engineers in reviewing and/or assessing the subsurface reservoir simulation models. For example, the data consistency reports can summarize well trajectory inconsistencies amongst data sources, erroneous perforation events, correction operations automatically implemented, and/or the like.

Moreover, various embodiments described herein can constitute one or more technical improvements over conventional subsurface reservoir simulation data assurance by utilizing computer automated systems and/or methods to perform data consistency and/or perforation consistency checks using conditional logic. For instance, various embodiments described herein can validate a vast amount of well trajectory data against multiple data sources prior to generation of the subsurface reservoir model simulation to check for data inconsistencies and/or trajectory distortions. In another instance, various embodiments described herein can automatically correct well attribute data to ensure consistency of well perforation events in relation to targeted geological zones for a vast amount of wells associated with the subsurface reservoir. Additionally, one or more embodiments described herein can have a practical application by automatically assessing input data (e.g., well trajectory and/or attribute data derived from deviation survey data) for data and perforation event consistencies via conditional logic that can be periodically updated (e.g., as new data issues are identified) and expeditiously implemented.

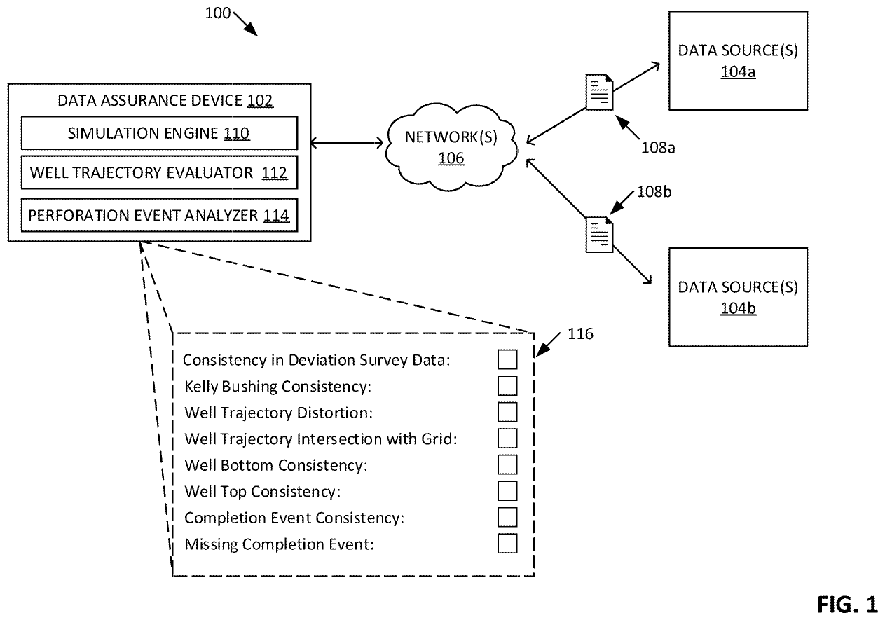

FIG. 1 illustrates a non-limiting example system 100 that can comprise the one or more data assurance devices 102 in accordance with one or more embodiments described herein. In various embodiments, the one or more data assurance devices 102 (e.g., a server, a desktop computer, a laptop, a hand-held computer, a programmable apparatus, a minicomputer, a mainframe computer, an Internet of things (“IoT”) device, and/or the like) can be operably coupled to (e.g., communicate with) a plurality of data sources 104 via one or more networks 106.

In various embodiments, the data sources 104 can be sources of deviation survey data 108. For instance, as shown in FIG. 1, a first data source 104a can supply a first set of deviation survey data 108a to the data assurance device 102 via the one or more networks 106, while a second data source 104b can also supply a second set of deviation survey data 108b to the data assurance device 102. Further, each set of deviations survey data 108 can characterize the same wells to be modeled in one or more subsurface reservoir simulations. For example, various features of the wells, such as the trajectory and completion events (e.g., location of perforations, squeezes, and/or plugbacks) associated with the wells, can be defined three-dimensionally (“3D”) (e.g., along X, Y, and/or Z coordinate axes) by a plurality of parameters included in the deviation survey data 108. Example parameters can include, but are not limited to: measured depth (“MD”) of the wells, X coordinate values of the wells, Y coordinate values, Z coordinate values, true vertical depth of the wells, azimuth of the wells, inclination of the wells, a combination thereof, and/or the like. Ideally, the deviation survey data 108 would be equivalent amongst the different data sources 104 for the same wells. In practice, there can be inconsistencies between the deviation survey data 108 from one data source 104 to another e.g. sometimes the inconsistencies can be introduced due to differences in deviation survey calculation methods. In various embodiments, the data assurance device 102 can evaluate the deviation survey data 108 consistency amongst the respective data sources 104 to ensure the accuracy of the resulting well trajectories.

The one or more networks 106 can comprise one or more wired and/or wireless networks, including, but not limited to: a cellular network, a wide area network (“WAN”), a local area network (“LAN”), a combination thereof, and/or the like. One or more wireless technologies that can be comprised within the one or more networks 106 can include, but are not limited to: wireless fidelity (“Wi-Fi”), a WiMAX network, a wireless LAN (“WLAN”) network, BLUETOOTH® technology, a combination thereof, and/or the like. For instance, the one or more networks 106 can include the Internet and/or the IoT. In various embodiments, the one or more networks 106 can comprise one or more transmission lines (e.g., copper, optical, or wireless transmission lines), routers, gateway computers, and/or servers. Further, the one or more data sources 104 and/or data assurance device 102 can comprise one or more network adapters and/or interfaces (not shown) to facilitate communications via the one or more networks 106.

As shown in FIG. 1, the data assurance device 102 can include a simulation engine 110, a well trajectory evaluator 112, and/or a perforation event analyzer 114. In various embodiments, the simulation engine 110 can generate one or more subsurface reservoir simulation models based on the deviation survey data 108. For example, the one or more subsurface reservoir simulation models can be 3D representations of a subsurface hydrocarbon reservoir. Additionally, the simulations can include 3D representations of one or more wells drilled into the terrane to access the hydrocarbon reservoir. As described herein, the simulation engine 110 can generate representations of the position and/or trajectory of the wells, as defined by deviation survey data 108, within the simulation in relation to the subsurface reservoir (e.g., hydrocarbon reservoir). Likewise, the simulation engine 110 can generate representations of one or more well features (e.g., perforations, squeezes, plugbacks, a combination thereof, and/or the like), as defined by the deviation survey data 108, in the well utilized to access the subsurface reservoir at targeted locations along the well trajectory. In various embodiments, the data assurance device 102 can analyze the accuracy of the wells represented in the subsurface reservoir simulation models via the well trajectory evaluator 112 and/or the perforation event analyzer 114.

The well trajectory evaluator 112 can analyze multiple sets of deviation survey data 108 associated with a given subsurface reservoir. As described herein, each set of deviation survey data 108 can define the same wells accessing the given subsurface reservoir. In various embodiments, the well trajectory evaluator 112 can detect inconsistencies between the sets of deviation survey data 108. Additionally, the well trajectory evaluator 112 can detect distortions in the trajectory of one or more wells defined by the deviation survey data 108 and/or represented in the one or more subsurface reservoir simulation models. For example, the well trajectory evaluator 112 can detect sudden bends and/or twists in the trajectory of one or more wells, which would be uncharacteristic of the well's trajectory in practice (e.g., uncharacteristic of the well's actual trajectory within the oil field associated with the subsurface reservoir). Moreover, the well trajectory evaluator 112 can generate one or more error reports summarizing identified data inconsistencies and/or well trajectory distortions.

The perforation event analyzer 114 can detect errors in the location of well completion events represented in the subsurface reservoir simulation models. Well completion events can include, but are not limited to: perforation sections of the well, squeezes, plugback positioned in the well, installation of inflow control devices (“ICD”) and packers along well tubing, installation of inflow control valves (“ICV”), perforation workover events, well test events, well sidetrack events a combination thereof, and/or the like. For example, the perforation sections can enable the well to be in fluid communication with one or more targeted zones of the subsurface reservoir. However, placing the perforation sections at locations other than the targeted zones can result in the well failing to retrieve hydrocarbons and/or retrieving hydrocarbons from an undesirable location within the subsurface reservoir. In various embodiments, the perforation event analyzer 114 can detect well perforation events represented in the subsurface reservoir simulation that extend beyond the targeted location.

In various embodiments, the data assurance device 102 can perform a plurality of data quality assurance checks 116 (e.g., via the well trajectory evaluator 112 and/or perforation event analyzer 114) to ensure the accuracy of wells modeled in one or more subsurface reservoir simulations (e.g., generated by the one or more simulation engines 110). As shown in FIG. 1, data quality assurance checks 116 performed by the data assurance device 102 can include, but are not limited to: checking for consistency in the deviation survey data 108 (e.g., consistency between multiple sets of deviation survey data 108 from respective data sources 104); checking for consistency in Kelly Bushing (“KB”) values between sets of deviation survey data 108; checking for well trajectory distortions (e.g., calculating the dogleg severity value of well trajectories); checking for consistency among intersection points between the well trajectory and grid horizons modeled in the subsurface reservoir simulation; checking for consistency in the bottom and/or top of wells, as defined in the deviation survey data 108; checking for consistency in the location, accuracy, and/or completion of perforated sections of the one or more wells modeled in the subsurface reservoir simulation; a combination thereof, and/or the like.

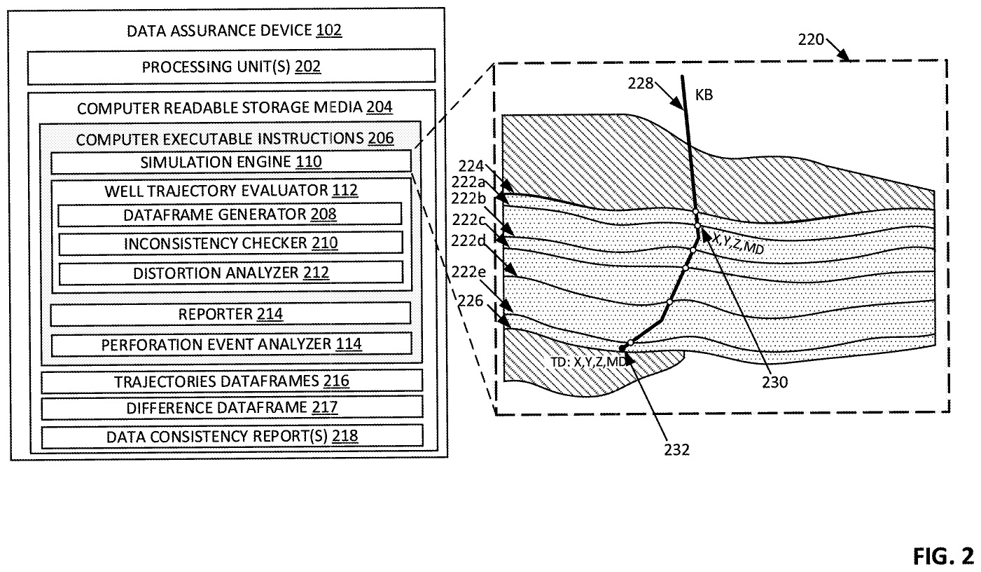

As shown in FIG. 2, the one or more data assurance devices 102 can comprise one or more processing units 202 and/or computer readable storage media 204. In various embodiments, the computer readable storage media 204 can store one or more computer executable instructions 206 that can be executed by the one or more processing units 202 to perform one or more defined functions. In various embodiments, the simulation engine 110, well trajectory evaluator 112, perforation event analyzer 114, and/or a reporter 207 can be computer executable instructions 206 and/or can be hardware components operably coupled to the one or more processing units 202. For instance, in some embodiments, the one or more processing units 202 can execute the simulation engine 110, well trajectory evaluator 112, perforation event analyzer 114, and/or reporter 207 to perform various functions described herein (e.g., evaluate well trajectory and/or analyze perforation events). For example, the well trajectory evaluator 112 can comprise a dataframe generator 208, inconsistency checker 210, and/or distortion analyzer 212. Additionally, the computer readable storage media 204 can store trajectories dataframes 216, difference dataframes 217, and/or data consistency reports 218.

The one or more processing units 202 can comprise any commercially available processor. For example, the one or more processing units 202 can be a general purpose processor, an application-specific system processor (“ASSIP”), an application-specific instruction set processor (“ASIPs”), or a multiprocessor. For instance, the one or more processing units 202 can comprise a microcontroller, microprocessor, a central processing unit, and/or an embedded processor. In one or more embodiments, the one or more processing units 202 can include electronic circuitry, such as: programmable logic circuitry, field-programmable gate arrays (“FPGA”), programmable logic arrays (“PLA”), an integrated circuit (“IC”), and/or the like.

The one or more computer readable storage media 204 can include, but are not limited to: an electronic storage device, a magnetic storage device, an optical storage device, an electromagnetic storage device, a semiconductor storage device, a combination thereof, and/or the like. For example, the one or more computer readable storage media 204 can comprise: a portable computer diskette, a hard disk, a random access memory (“RAM”) unit, a read-only memory (“ROM”) unit, an erasable programmable read-only memory (“EPROM”) unit, a CD-ROM, a DVD, Blu-ray disc, a memory stick, a combination thereof, and/or the like. The computer readable storage media 204 can employ transitory or non-transitory signals. In one or more embodiments, the computer readable storage media 204 can be tangible and/or non-transitory. In various embodiments, the one or more computer readable storage media 204 can store the one or more computer executable instructions 206 and/or one or more other software applications, such as: a basic input/output system (“BIOS”), an operating system, program modules, executable packages of software, and/or the like.

The one or more computer executable instructions 206 can be program instructions for carrying out one or more operations described herein. For example, the one or more computer executable instructions 206 can be, but are not limited to: assembler instructions, instruction-set architecture (“ISA”) instructions, machine instructions, machine dependent instructions, microcode, firmware instructions, state-setting data, configuration data, source code, object code, a combination thereof, and/or the like. For instance, the one or more computer executable instructions 206 can be written in one or more procedural programming languages. Although FIG. 2 depicts the computer executable instructions 206 stored on computer readable storage media 204, the architecture of the system 100 is not so limited. For example, the one or more computer executable instructions 206 can be embedded in the one or more processing units 202.

FIG. 2 illustrates a non-limiting example subsurface reservoir simulation model 220 that can be generated by the simulation engine 110 and analyzed by the well trajectory evaluator 112. In various embodiments, the well trajectory evaluator 112 perform one or more data consistency checks described herein prior to exporting the trajectory data (e.g., the assessed deviation survey data 108) to the simulation engine 110 for generating the subsurface reservoir simulation models. The subsurface reservoir simulation model 220 shown in FIG. 2 exemplifies a high quality model that can be achieved based on input data that was quality controlled by the well trajectory evaluator 112 in accordance with various embodiments described herein.

For example, subsurface reservoir simulation model 220 can be generated by the simulation engine 110 based on deviation survey data 108 received by the data assurance device 102. The example subsurface reservoir simulation model 220 can include a plurality of simulation grid horizons 222, a grid top 224, and/or a grid bottom 226. The solid black line can represent the trajectory 228 of a given well through the grid top 224, grid horizons 222, and grid bottom 226, where the grid horizons 222 can correspond to one or more zones of the subsurface reservoir (e.g., hydrocarbon reservoir). For example, the example subsurface reservoir simulation model 220 shown in FIG. 2 comprises first grid horizon 222a, second horizon 222b, third grid horizon 222c, fourth grid horizon 222d, and fifth grid horizon 222c. However, the subsurface reservoir simulations can model additional, or fewer, grid horizons 222.

In various embodiments, the well trajectory evaluator 112 can validate the KB values and trajectory data associated with each well against multiple sets of deviation survey data 108 received from multiple data sources 104. Advantageously, assuring the quality of the KB and well trajectory data can mitigate errors in modeling various well completion events. For example, well features, such as perforated sections of the well, may be modelled incorrectly where there are inconsistencies in the well KB value and/or well trajectory defined in the deviation survey data 108.

In various embodiments, the dataframe generator 208 can generate a trajectories dataframe 216 for each set of deviation survey data 108 received from a respective data source 104, where the trajectories dataframes 216 can define the trajectory of each well associated with a given subsurface reservoir in relation to the grid horizons 222 and/or 3D coordinates modeled in the subsurface reservoir simulation. For each well of each set of deviation survey data 108, the dataframe generator 208 can extract the intersection points 230 (e.g., represented by white circles in FIG. 2) where the trajectory 228 of a well intersects with the grid top 224, a grid horizon 222, and/or the grid bottom 226. The position of the intersection points 230 can be defined in three dimensions along the X, Y, and/or Z coordinate along the well MD. Additionally, the dataframe generator 208 can extract the target depth (“TD”) point 232, which can be defined by the X, Y, Z, and/or MD parameters for the last point of the trajectory 228 for the given well. Moreover, the well dataframe generator 208 can extract the KB elevation value for the trajectory 228 of each well.

In one or more embodiments, the number of parameters per well, NA, for each trajectory 228 can be characterized by Equation 1.

Nₜ=(4*N_{Horizons})+4+1 (1)

Where N_{Horizons} is the total number of grid horizons 222 in the simulation grid modeling the subsurface reservoir.

For example, where a well trajectory 228 intersects a simulation grid having five grid horizons 222, the total number of parameters will be 25. The total number of parameters per well, Nₜ, and the extracted parameter values can be stored in a trajectories dataframe 216, which defines the trajectory 228 of each well described by the deviation survey data 108 from a data source 104. In various embodiments, the dataframe generator 208 can generate a trajectories dataframe 216 for each data source 104; thereby generating a plurality of trajectories dataframes 216 characterizing the same wells in relation to the same subsurface reservoir simulation.

The total number of parameters per data source 104, N_{DS}, can be characterized by Equation 2.

N_{DS}=N_{w}*Nₜ (2)

Where N_{w} is the total number of wells defined by the deviation survey data 108 and analyzed by the well trajectory evaluator 112 for a given subsurface reservoir. For instance, where the total number of parameters per well, Nₜ, is 25 and the total number of wells, N_{w}, is 1000, the total number parameters per dataframe 216, N_{DS}, will be 25,000. Where well trajectory evaluator 112 is analyzing deviation survey data 108 from two data sources 104, the dataframe generator 208 can calculate two trajectories dataframes 216, resulting in a total number of 50,000 evaluated parameters.

Additionally, the inconsistency checker 210 can calculate a difference between the parameter values of the trajectories dataframes 216 and generate a difference dataframe 217. For example, the inconsistency checker 210 can calculate a difference between the trajectories dataframes 216 for each parameter value and store the difference in a difference dataframe 217 in accordance with Equation 3 below.

DIFF_{DF}=|(x₁²,x₂², . . . ,x_{N}_{_{DS}}²)−(x₁¹,x₂¹, . . . ,x_{N}_{_{DS}}¹)| (3)

Where “DIFF_{DF}” is the difference dataframe 217, “x₁²” is the first data element of the second trajectories dataframe 216, and “x₁¹” is the first data element of the first trajectories dataframe 216. By calculating the difference between the parameter values of the trajectories dataframes 216, the inconsistency checker 210 can identify differences between how respective sets of deviation survey data 108 define the trajectories 228 of the wells.

In various embodiments, the inconsistency checker 210 can further compare the difference values of the differences dataframe 217 to one or more defined threshold values to determine whether the differences amount to an error in the trajectory 228 of one or more wells. For example, one or more users of the system 100 can define a KB tolerance and/or a trajectory tolerance. Where the difference value of a parameter between the trajectories dataframes 216 exceeds the associated threshold, the inconsistency checker 210 can identify an error with the trajectory 228 of the well defined by the given parameter. For example, the inconsistency checker 210 can label a well as having a KB error if the difference in the KB value for the well between two trajectories dataframes 216 (e.g., thereby between two data sources 104) is greater than the KB tolerance. In another example, the inconsistency checker 210 can label a well as having a trajectory error if the difference in the X, Y, Z, or MD value at any intersection point 230 for the well between two trajectories dataframes 216 (e.g., thereby between two data sources 104) is greater than the trajectory tolerance. In a further example, the inconsistency checker 210 can label a well as having a TD error if the difference in the X, Y, Z, or MD value at the TD point 232 for the well between two trajectories dataframes 216 (e.g., thereby between two data sources 104) is greater than the trajectory tolerance. In various embodiments, the inconsistency checker 210 can detect a single error associated with a well or multiple errors associated with the well.

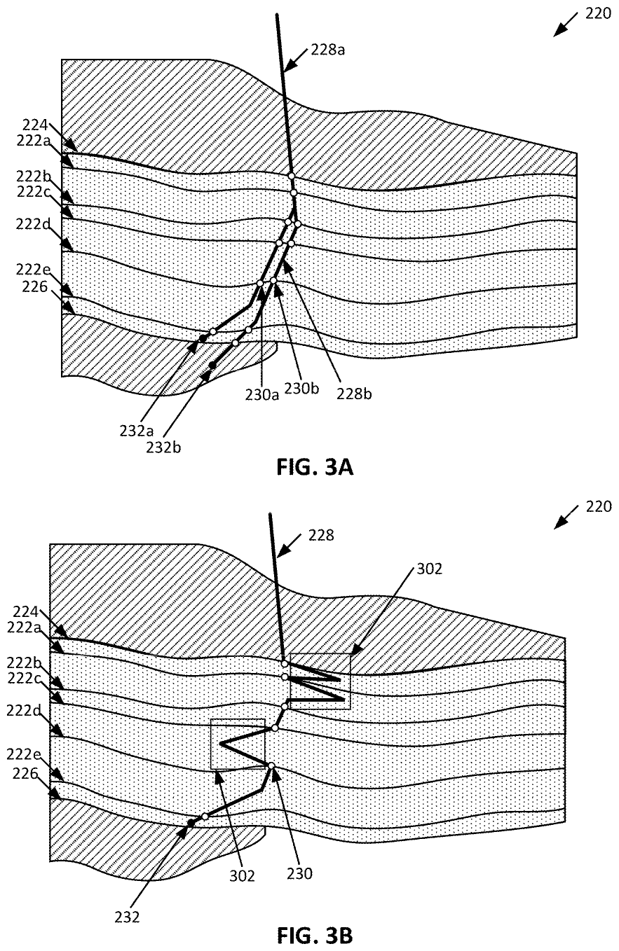

FIG. 3A illustrates a non-limiting example of the subsurface reservoir simulation model 220 representing a well based on two sets of deviation survey data 108. In subsurface reservoir simulation model 220 exemplified in FIG. 3A, inconsistencies between the sets of deviation survey data 108 from different data sources 104 results in different trajectories 228 of the well. As shown in FIG. 3A, the bold black line represents a first trajectory 228a of the well, as defined by a first set of deviation survey data 108a; while the dashed line represents a second trajectory 228b of the well, as defined by a second set of deviation survey data 108b. For example, the first trajectory 228a is defined via a plurality of intersection points 230a that differ from intersection points 230b that define the second trajectory 228b. For clarity, an intersection point 230a of the first trajectory 228a and the corresponding intersection point 230b of the second trajectory 228b are labeled in FIG. 3A to exemplify the deviation of the possible trajectories 228 for the well. The difference between the location of the intersection points 230a, 230b between the first and second trajectories 228a. 228b can be reflected in the difference dataframe 217. Where said difference is greater than the trajectory tolerance, the inconsistency checker 210 can label the well exemplified in FIG. 3A as having a trajectory error. In another example, the first trajectory 228a terminates in a TD point 232a that is different than the TD point 232b of the second trajectory 228b. The difference between the location of the TD points 232a, 232b between the first and second trajectories 228a, 228b can also be reflected in the difference dataframe 217. Where said difference is greater than the trajectory tolerance, the inconsistency checker 210 can label the well exemplified in FIG. 3A as having a TD error.

Referring again to FIG. 2, the distortion analyzer 212 can analyze the deviation survey data 108 to identify distorted trajectories 228 characterized by sharp and/or sudden changes in direction. For example, the distortion analyzer 212 can execute a distortion analysis algorithm that reviews the rate of change of the MD values with respect to the Z coordinate values to identify sharp changes in the dogleg severity (“DLS”) attribute of the well's trajectory 228. For instance, the distortion analyzer 212 can compare the trajectory's 228 DLS value to a defined DLS tolerance. Where the DLS value exceeds the DLS tolerance, the distortion analyzer 212 can determine that the trajectory 228 is distorted.

FIG. 3B illustrates a non-limiting example of the subsurface reservoir simulation model 220 representing a distorted well trajectory 228. As shown in FIG. 3B, the example trajectory 228 can have the same intersection points 230 and TD point 232 as the proper trajectory 228 shown in FIG. 2; however, the trajectory 228 shown in FIG. 3 is distorted between multiple intersection points 230. In particular, the trajectory 228 exemplified in FIG. 3 includes at least two distortion sections 302 (e.g., delineated by dashed boxes for clarity), where the trajectory 228 sharply changes direction between intersection points 230. For instance, the distortion analyzer 212 can execute the distortion analysis algorithm to analyze the DLS attribute of the trajectory 228 along the MD. In the distortion sections 302 shown in FIG. 3, the trajectory 228 can have large DLS values that exceed the DLS tolerance; thereby the distortion analyzer 212 can identify the trajectory 228 as distorted at the distortion sections 302.

Referring again to FIG. 2, the data assurance device 102 can further comprise a reporter 207, which can generate one or more data consistency reports 218. In various embodiments, the data consistency reports 218 can summarize the trajectories dataframes 216, difference dataframes 217, errors detected by the inconsistency checker 210 (e.g., KB errors, trajectory errors, and/or TD errors), and/or errors detected by the distortion analyzer 212 (e.g., trajectory distortions). For example, the data consistency reports 218 can include text, graphs, charts, illustrations, a combination thereof, and/or the like. In one or more embodiments, the reporter 207 can share the one or more data consistency reports 218 with one or more users of the system 100 to facilitate correction of well trajectories 228 with identified errors in the subsurface reservoir simulation. For instance, where the calculated differences are outside of the defined tolerance (e.g., where errors are detected), the subject wells can be flagged for review by one or more subject matter expertise to identify which set of deviation survey data is to be utilized.

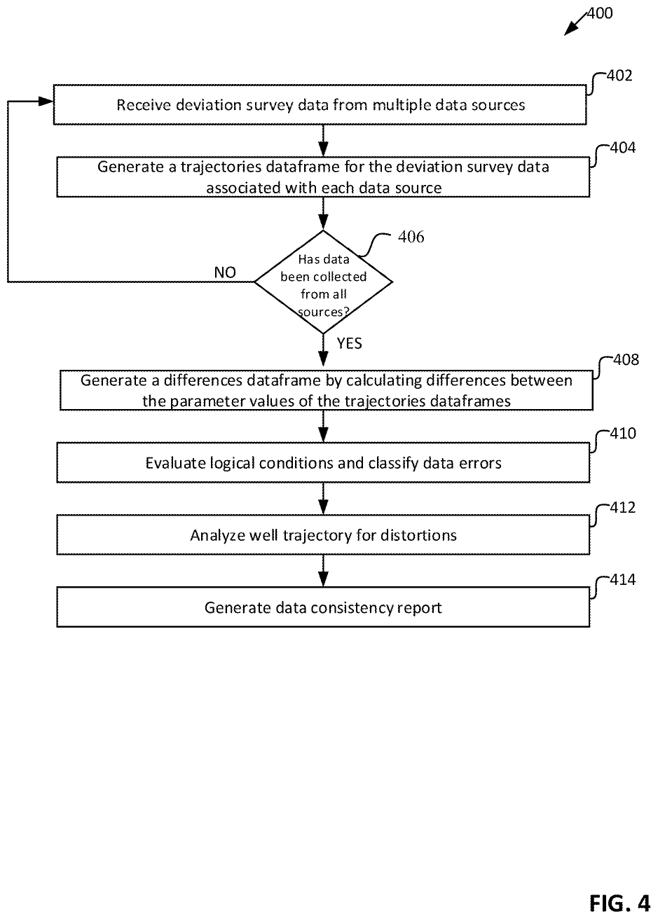

In view of the foregoing structural and functional features described above, example methods will be better appreciated with reference to FIG. 4. While, for purposes of simplicity of explanation, the example methods of FIG. 4 are shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the methods.

FIG. 4 illustrates a non-limiting example computer-implemented method 400 that can be implemented by the system 100 to evaluate the accuracy of well trajectories modeled by one or more subsurface reservoir simulations (e.g., as exemplified by the trajectory 228 in subsurface reservoir simulation model 220) in accordance with one or more embodiments described herein. In various embodiments, the method 400 can be executed to evaluate the amount of consistency between sets of deviation survey data 108 originating from different data sources 104. Additionally, the method 400 can be executed to identify distorted well trajectories in the subsurface reservoir simulations modeling the deviation survey data 108. In various embodiments, method 400 can be implemented to perform data consistency checks prior to exporting input data (e.g., trajectory data defined by deviation survey data 108) to the simulation engine 110 for modeling.

At 402, the method 400 can comprise receiving (e.g., via the well trajectory evaluator 112), by a system 100 operably coupled to one or more processing units 202, deviation survey data 108 from multiple data sources 104. In accordance with various embodiments described herein, the deviation survey data 108 can include multiple parameters defining the trajectory of wells accessing the given subsurface reservoir in a 3D environment, such as: well MD; X, Y, and/or Z coordinates along the well trajectory; true vertical depth of the well; azimuth of the well trajectories; and/or inclination of the well trajectories. In various embodiments, a respective set of deviation survey data 108 can be received from multiple data sources 104, where each set of deviation survey data 108 defines the same wells in relation to the same subsurface reservoir. Deviation survey data 108 can be collected from multiple data sources 104 to assess the quality of the data by identifying inconsistencies in the deviation survey data 108 from different data sources 104 (e.g., high data quality assurance is associated with minimal deviations between deviation survey data 108 from different data sources 104).

At 404, the method 400 can comprise generating (e.g., via dataframe generator 208), by the system 100, a trajectories dataframe 216 for the deviation survey data 108 associated with each data source 104. In accordance with various embodiments described herein, the dataframe generator 208 can calculate the KB value, intersection points 230, and/or TD point 232 associated with each well based on the deviation survey data 108. For example, generating the trajectories dataframes 216 at 404 can comprise generating a respective trajectories dataframe 216 for each set of deviation survey data 108 received at 402 (e.g., generating a respective trajectories dataframe 216 for each data source 104).

At 406, the method 400 can comprise determining (e.g., via dataframe generator 208), by the system 100, whether deviation survey data 108 has been collected from all the data sources 104. For example, each trajectories dataframe 216 can be generated with a unique identify associating the trajectories dataframe 216 to the data source 104 that supplied the deviation survey data 108 that characterizes the trajectories data frame 216. In one or more embodiments, the dataframe generator 208 can compare the unique identifiers of the generated trajectories dataframes 216 to a list of data sources 104. Where one or more trajectories dataframes 216 is missing for one or more data sources 104 included in the list, the method 400 can proceed back to feature 402 and the well trajectory evaluator 112 can query the one or more missed data sources 104 for deviation survey data 108. Where trajectories dataframes 216 are associated with each data source 104 listed, the method 400 can proceed to feature 408.

At 408, the method 400 can comprise generating (e.g., via the inconsistency checker 210), by the system 100, a differences dataframe 217 by calculating differences between the parameter values of the trajectories dataframes 216. In accordance with various embodiments described herein, the inconsistency checker 210 can calculate differences between a parameter defined in a first trajectories dataframe 216 and an associated parameter defined in a second trajectories dataframe 216. For example, the inconsistency checker 210 can calculate the difference in the X. Y. Z, and/or MD value of an intersection point defined in the first trajectories dataframe 216 and the X, Y, Z. and/or MD value of the same intersection point, as defined in the second trajectories dataframe 216. The differences calculated when generating the differences dataframe 217 at 408 can amount to inconsistencies between sets of deviation survey data 108 received from multiple data sources 104. Where more than two sets of deviation survey data 108 are analyzed, each trajectories dataframe 216 can be compared to two or more other trajectories dataframes 216 to generate multiple difference dataframes 217 at 408.

At 410, the method 400 can comprise evaluating (e.g., via the inconsistency checker 210), by the system 100, logical conditions associated with the calculated differences stored in the difference dataframe 217 and classify types of errors characterizing the well trajectory. In accordance with various embodiments described herein, the calculated differences can be compared to one or more defined thresholds, such as a KB tolerance and/or a trajectory tolerance. Where the calculated differences exceed the defined thresholds, the inconsistency checker 210 can classify the well as comprising an error (e.g., a KB error, a trajectory error, and/or a TD error).

At 412, the method 400 can comprise analyzing (e.g., via distortion analyzer 212), by the system 100, the well trajectories, as defined by the deviation survey data 108, for one or more distortions characterized by sudden changes in direction. In accordance with various embodiments described herein, a DLS value can be calculated for one or more sections of the well trajectory (e.g., between intersection points with horizon grids of the subsurface reservoir simulation) by a distortion analysis algorithm. Where the calculated DLS value exceeds a defined DLS tolerance, the associated section of the well trajectory can be identified as distorted (e.g., via the distortion analyzer 212). In one or more embodiments, the analysis for well trajectory distortions can be performed prior to generating the differences dataframes 217 at 408 (e.g., analyzing the well trajectories for distortions can serve as a pre-processing step).

At 414, the method 400 can comprise generating (e.g., via reporter 207), by the system 100, one or more data consistency reports 218. In accordance with one or more embodiments described herein, the one or more data consistency reports 218 can summarize the one or more trajectory dataframes 216, the difference dataframe 217, inconsistency errors classified at 410 (e.g., KB errors, trajectory errors, and/or TD errors), and/or trajectory distortions identified at 412. In various embodiments, the one or more data consistency reports 218 can be associated with one or more subsurface reservoir simulations models and/or can be shared with one or more users of the system 100 to finalize well trajectories.

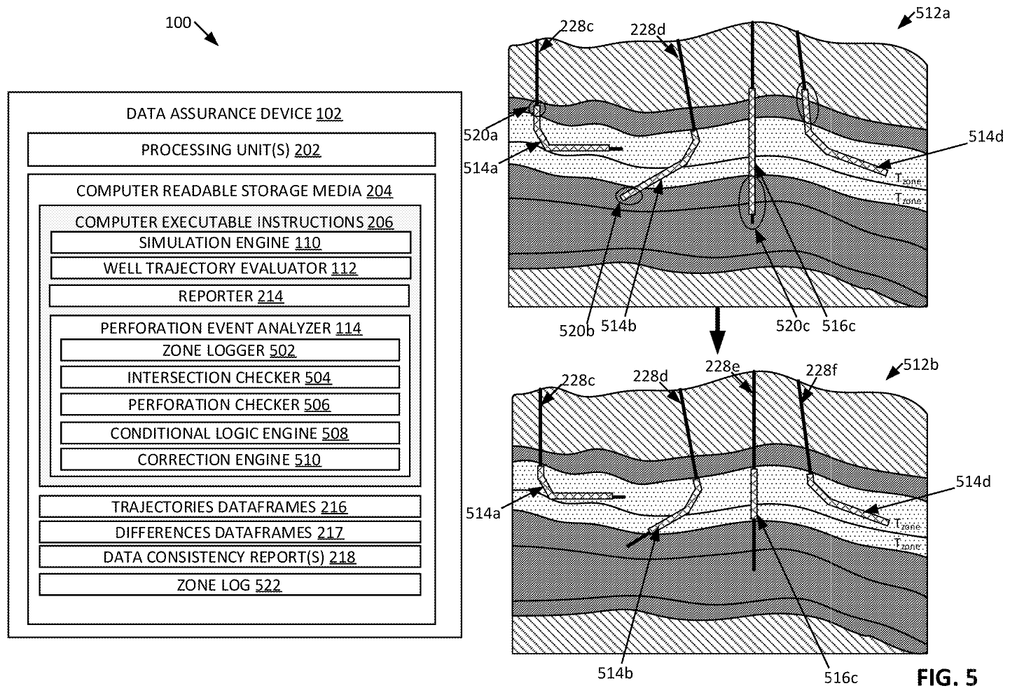

In accordance with various embodiments described herein, the perforation event analyzer 114 can perform one or more data quality assurance checks 116 on well perforation events modeled in the one or more subsurface reservoir simulations. As shown in FIG. 5, the perforation event analyzer 114 can comprise zone logger 502, intersection checker 504, perforation checker 506, conditional logic engine 508, and/or correction engine 510. In various embodiments, the perforation event analyzer 114 can analyze the perforation features of each well modeled in the subsurface reservoir simulation to determine whether the perforations are confined to defined zones of interest of the of the well trajectory.

In various embodiments, the perforation event analyzer 114 can perforation consistency checks and/or corrections prior to exporting the well attribute data (e.g., sourced from the deviation survey data 108) to the simulation engine for generating the subsurface reservoir simulation models. To case understanding of the objectives and results of the various features of the perforation event analyzer 114 described herein, said features are described with reference to subsurface reservoir simulation models to provide a visual aid. However, the various features of the perforation event analyzer 114 described herein can be executed prior to generation of the models.

For example, FIG. 5 illustrates another example subsurface reservoir simulation model 512 (e.g., generated by simulation engine 110) that can be analyzed by the perforation event analyzer 114. As shown in FIG. 5, the example subsurface reservoir simulation model 512 includes four trajectories 228 (e.g., trajectories 228c, 228d, 228c, 228f) associated with four respective wells. Additionally, each well has a perforation event 514 (e.g., perforation events 514a, 514b, 514c, 514d) along each of the trajectories 228. Further, the simulation grid can delineate one or more zones (e.g., subsurface geographical regions) targeted for fluid communication with the wells (e.g., where targeted zones are delineated by “T_{zone}” in FIG. 5). In various embodiments, the perforation event analyzer 114 can detect erroneous perforated portions 520 of the perforation events 514, where the perforation events 514 extend beyond the targeted zones T_{zone} of the subsurface reservoir and into the non-targeted zones. For instance, the example subsurface reservoir simulation model 512 includes four erroneous perforated portions 520 (e.g., erroneous perforation portions 520a, 520b, 520c, and 520d), which are circled for clarity in FIG. 5.

Additionally, the perforation event analyzer 114 can execute one or more correction operations to adjust the location and/or dimensions of the perforation events 514 to avoid erroneous perforated portions 520. For example, where the perforation event analyzer 114 detects an erroneous perforation portion 520 in a perforation event 514, the perforation event analyzer 114 can redefine the architecture of the perforation event 514 to confine the perforation event 514 within the one or more targeted zones T_{zone}. For instance, FIG. 5 depicts the non-corrected example subsurface reservoir simulation model 512a analyzed by the perforation event analyzer 114, and the corrected example subsurface reservoir simulation model 512b after one or more correction operations executed by the perforation event analyzer 114 to remedy erroneous perforation portions 520.

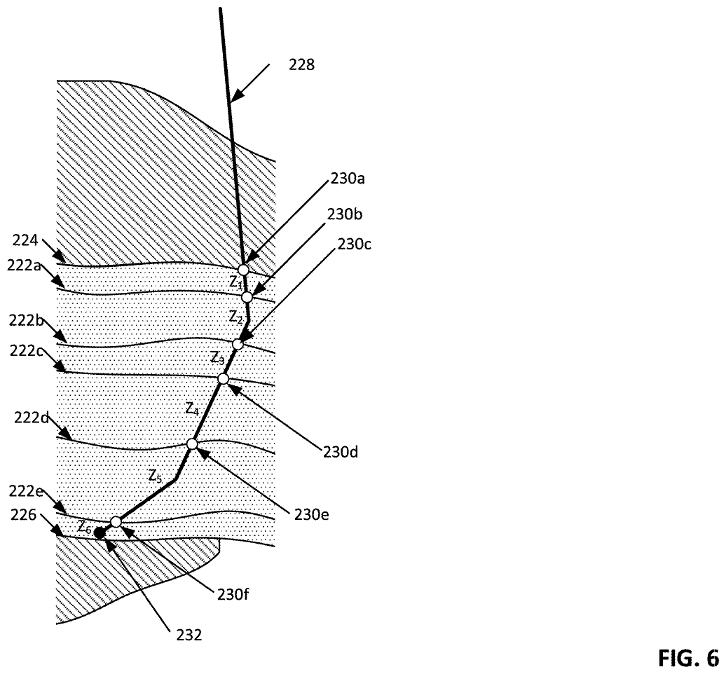

In various embodiments, analysis by the perforation event analyzer 114 can begin with the zone logger 502, which can generate a zone log 522 defining the zones modeled by the subsurface reservoir simulation in relation to the trajectories 228 of the wells. For clarity, various features of the zone logger 502 are exemplified with regards to FIG. 6, which depicts a portion of the example subsurface reservoir simulation model 220. As shown in FIG. 6, zones can be defined by the grid top 224, grid horizons 222, and/or grid bottom 226. For example, the example subsurface reservoir simulation model 220 comprises five grid horizons 222, which the zone logger 502 can utilize to define six zones, each labelled with a unique identifier, such as “Zₓ”, where “x” is an integer unique to the zone, such as: Z₁, Z₂, Z₃, Z₄, Z₅, Z₆.

Further, the zone logger 502 can associate each data point defining the trajectory 228 of a well with a zone based on the MD value of the data point. For example, each data point along the trajectory 228 having a MD value between the MD value of the first intersection point 230a and the MD value of the second intersection point 230b can be associated with the first zone Z₁. Likewise, each data point along the trajectory 228 having a MD value between the MD value of the second intersection point 230b and the MD value of the third intersection point 230c can be associated with the first zone Z₂. Thereby, the zone logger 502 can label each data point defining the trajectory 228 (e.g., from a MD value of 0 to the MD value of the TD point 232, “TD_{MD}”) with a zone of the subsurface reservoir simulation to generate the zone log 522. Additionally, the zone mapping process can be repeated for each well modeled by the subsurface reservoir simulation, such that the zone log 522 can define which zones each well intercepts along its trajectory 228.

Moreover, the zone logger 502 can identify one or more of the zones as targeted zones T_{zone}. For example, one or more users of the system 100 can define one or more zones as targeted zones T_{zone}, and the zone logger 502 can calculate a Boolean log, T, along the trajectory 228 of each well in accordance with Equation 4.

$$T = \{ \begin{matrix}1 & if ( ZONES = {T}_{zone} ) \\ 0 & if ( ZONES \neq {T}_{zone} )\end{matrix} \qquad ( 4 )$$

Referring again to FIG. 5, the intersection checker 504 can analyze the zone log 522 to determine whether a given well is defined by a trajectory 228 that intersects with the one or more targeted zones T_{zone}. In various embodiments, the intersection checker 504 can utilize conditional logic to analyze the trajectory 228 of each well in relation to the one or more targeted zones T_{zone}. For example, the intersection checker 504 can determine whether a trajectory 228 extends into a targeted zone T_{zone} in accordance with Equation 5.

$${C}_{1} = \{ \begin{matrix}True if ( {\sum }_{0}^{{MD}_{TD}} T = 0 ) \\ False if ( {\sum }_{0}^{{MD}_{TD}} T > 0 )\end{matrix} \qquad ( 5 )$$

Where “C₁” can be a data consistency analysis determination that the given well trajectory 228 does not intersect with a targeted zone T_{zone}.

Additionally, the perforation checker 506 can analyze the subsurface reservoir simulation and extract the minimum MD, “MD_{perf.min}”, of a perforation event 514 per trajectory 228 and the maximum MD, “MD_{perf.max}”, of the perforation event 514 per trajectory 228. Thereby, the perforation checker 506 can define the position of the perforation event 514 along the trajectory 228. Further, the perforation checker 506 can calculate the mean perforation zone variable, “Pₘₑₐₙ”, in accordance with Equation 6.

$${P}_{mean} = \{ \begin{matrix}\overline{ZONES} if ( MD \geq {MD}_{perf , min} and MD \leq {MD}_{perf , max} ) \\ 0 , otherwise\end{matrix} \qquad ( 6 )$$

Moreover, the perforation checker 506 can extract the zones log value at the top perforation MD, “Pₜₒₚ”, for the perforation event 514 and the bottom perforation MD, “P_{bottom}”, from the zone log 522 in accordance with Equations 7 and 8.

$$\begin{matrix}{P}_{top} = \{ \begin{matrix}ZONES if ( MD = {MD}_{perf , min} ) \\ Undefined , otherwise\end{matrix} & ( 7 ) \\ {P}_{bottom} = \{ \begin{matrix}ZONES if ( MD = {MD}_{perf , max} ) \\ Undefined , otherwise\end{matrix} & ( 8 )\end{matrix}$$

In addition, the conditional logic engine 508 can evaluate a series of conditional statements, each of which can test for a specific data consistency scenario with respect to the perforation events 514 of the modeled wells. For example, the conditional logic engine 508 can evaluate conditional statements C₂ to C₈ in accordance with Equations 9-15.

$$\begin{matrix}{C}_{5} = \{ \begin{matrix}True if ( {P}_{mean} \neq {T}_{zone} ) and ( {P}_{top} = {T}_{zone} ) and ( {P}_{bottom} \neq {T}_{zone} ) \\ False , otherwise\end{matrix} & ( 12 ) \\ {C}_{6} = \{ \begin{matrix}True if ( {P}_{mean} \neq {T}_{zone} ) and ( {P}_{top} \neq {T}_{zone} ) and ( {P}_{bottom} \neq {T}_{zone} ) \\ False , otherwise\end{matrix} & ( 13 ) \\ {C}_{7} = \{ \begin{matrix}True if ( {P}_{mean} \neq {T}_{zone} ) and ( {P}_{top} = {T}_{zone} ) and ( {P}_{bottom} = {T}_{zone} ) \\ False , otherwise\end{matrix} & ( 14 )\end{matrix}$$

$${C}_{8} = \{ \begin{matrix}True if ( {P}_{mean} = {T}_{sone} ) \\ False , otherwise\end{matrix} \qquad ( 15 )$$

Where the conditional statements C₂ to C₈ can be defined in accordance with Table 1, below.

TABLE 1

| Conditional | |
|---|---|
| Statement | |
| (If True) | Data Consistency Analysis Determination |
| C₁ | Well trajectory not in a targeted zone |
| C₂ | Bottom of the perforation event is greater than the well's |
| | TD point |
| C₃ | Well trajectory is outside the grid of the subsurface |
| | reservoir simulation |
| C₄ | Top of the perforation event is not in a targeted zone |
| C₅ | Bottom of the perforation event is not in a targeted zone |
| C₆ | Top and Bottom of the perforation event are not in a |
| | targeted zone |
| C₇ | A portion of the perforation event is not in a targeted |
| | zone |
| C₈ | The perforation event is in a targeted zone |

In various embodiments, the conditional logic engine 508 can repeat the evaluation of the conditional statements with regards to analyze each perforation event 514 of each well. Once the perforation events 514 are analyzed by the conditional logic engine 508, the correction engine 510 can perform one or more correction operations depending on the conditional statement associated with each perforation event 514. In one or more embodiments, the correction engine 510 can execute the correction operations automatically. In some embodiments, the correction engine 510 can execute the correction operations upon approval of a user of the system 100. Table 2 delineates correction operations that can be implemented by the correction engine 510 based on the associate conditional statement being true. Additionally, in various embodiments one or more of the conditional statements can be reported to a user of the system 100. For example, the reporter 207 can include the status of one or more perforation events 514 within the data consistency report 218.

TABLE 2

| Conditional | |
|---|---|
| Statement | Correction Operation |
| C₁ | No automatic correction operation implemented - |
| | conditional statement reported |
| C₂ | Adjust the MD_{perf, max} to equal the MD_{TD} |
| C₃ | No automatic correction operation implemented - |
| | conditional statement reported |
| C₄ | Adjust the MD_{perf, min} to equal the MD of the Pₜₒₚ |
| C₅ | Adjust the MD_{perf, max} to equal the MD of the P_{bottom} |
| C₆ | Adjust the MD_{perf, min} to equal the MD of the Pₜₒₚ and |
| | adjust the MD_{perf, max} to equal the MD of the P_{bottom} |
| C₇ | Remove portion of perforation event 514 not in a |
| | targeted zone |
| C₈ | No automatic correction operation implemented - |
| | conditional statement reported |

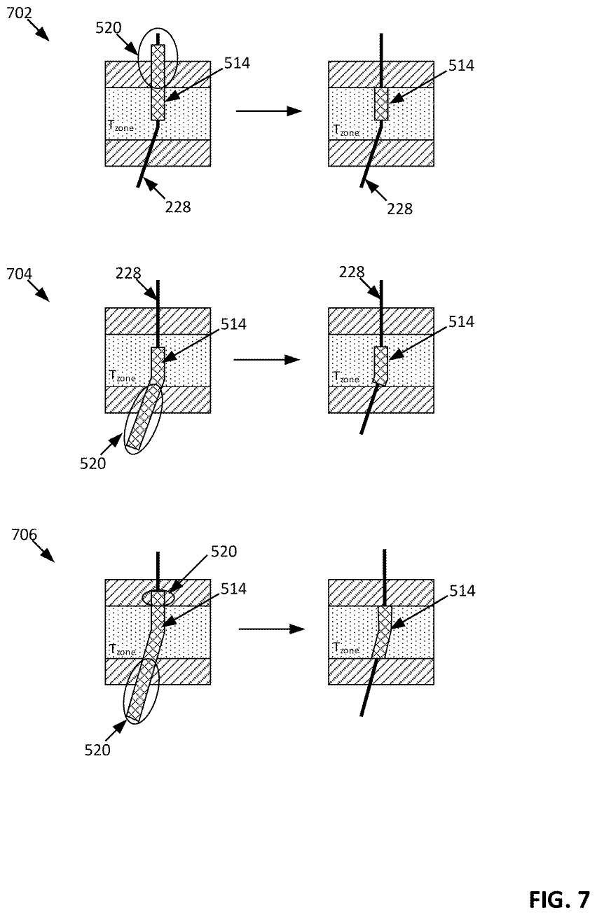

FIG. 7 illustrates various example perforation events 514 with erroneous perforated portions 520 that can be remedied via one or more correction operations performed by the correction engine 510 in accordance with Table 2. For example, scenario 702 depicts a perforated event 514 having a MD_{perf.min} value that is less than the Pₜₒₚ value; thereby, the perforated event 514 extends outside the targeted zone T_{zone} (e.g., extends through a MD that is shallower than the MD range defining the targeted zone T_{zone} along the trajectory 228), as described by conditional statement C₄. As shown in FIG. 7, the correction engine 510 can adjust the value of the MD_{perf.min} value to equal the Pₜₒₚ value (e.g., in accordance with Table 4).

In another example, scenario 704 depicts a perforated event 514 having a MD_{perf.max} value that is greater than the P_{bottom} value; thereby, the perforated event 514 extends outside the targeted zone T_{zone} (e.g., extends through a MD that is deeper than the MD range defining the targeted zone T_{zone} along the trajectory 228), as described by conditional statement C₅. As shown in FIG. 7, the correction engine 510 can adjust the value of the MD_{perf.max} value to equal the P_{bottom} value (e.g., in accordance with Table 4).

In a further example, scenario 706 depicts a perforated event 514 having both: (1) a MD_{perf.min} value that is less than the Pₜₒₚ value; thereby, the perforated event 514 extends outside the targeted zone T_{zone}; and (2) a MD_{perf.max} value that is greater than the P_{bottom} value; thereby, the perforated event 514 extends outside the targeted zone T_{zone}, as described by conditional statement C₆. As shown in FIG. 7, the correction engine 510 can: (1) adjust the value of the MD_{perf.min} value to equal the Pₜₒₚ value; and (2) adjust the value of the MD_{perf.max} value to equal the P_{bottom} value.

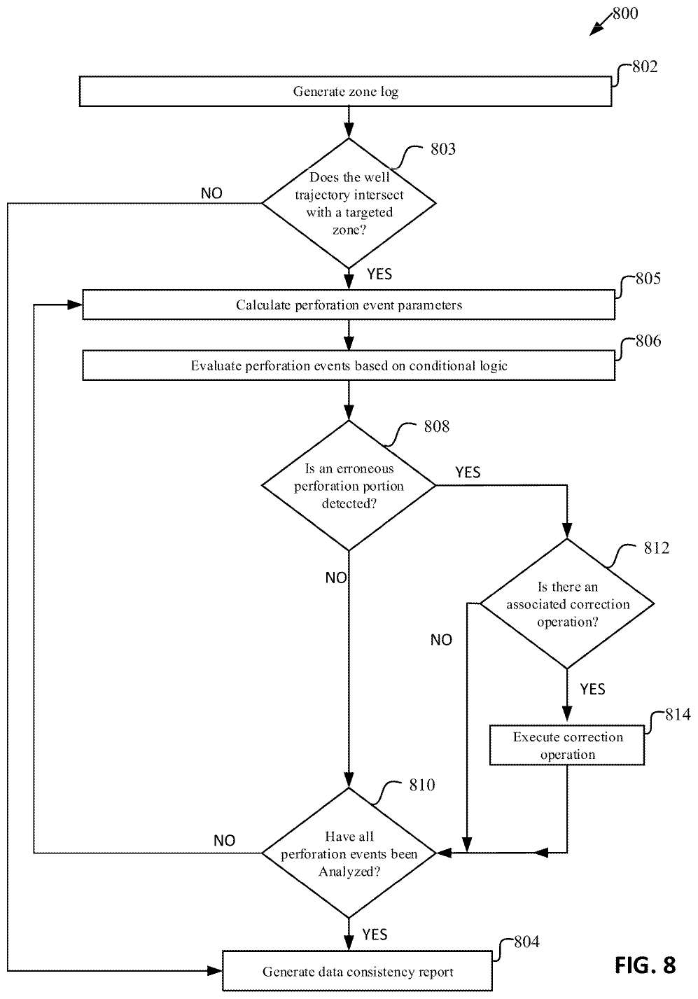

FIG. 8 illustrates a flow diagram of a non-limiting example computer-implemented method 800 that can be executed by the system 100 to evaluate perforation events 514 of one or more wells modeled by a subsurface reservoir simulation in accordance with one or more embodiments described herein. While, for purposes of simplicity of explanation, the example methods of FIG. 8 are shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the methods. In various embodiments, the data assurance device 102 (e.g., via perforation event analyzer 114) can implement method 800 after executing method 400. In various embodiments, method 800 can be implemented to perforation event consistency checks prior to exporting input data (e.g., well attribute data defined by deviation survey data 108) to the simulation engine 110 for modeling.

At 802, the method 800 comprises generating (e.g., via zone logger 502), by a system 100 operably coupled to one or more processing units 202, one or more zone logs 522. In accordance with various embodiments described herein, the one or more zone logs 522 can define one or more zones modeled by the subsurface reservoir simulation along with a well's trajectory in relation to the zones. For example, generating the zones at 802 can comprise defining a plurality of zones based on the interceptions points 230 of a trajectory 228 and associating trajectory data points with the defined zones based on MD parameters (e.g., as exemplified in FIG. 6). Additionally, the zone logger 502 can identify one or more zones as targeted zones T_{zone} for the positioning of perforation events 514 (e.g., the zone logger 502 can identify targeted zones T_{zone} in accordance with one or more preferences set by a user of the system 100).

At 803, the method 800 can comprise determining (e.g., via intersection checker 504), by the system 100, whether the well trajectory intersects with a targeted zone T_{zone}. In accordance with various embodiments described herein, the intersection checker 504 can employ Equations 4 and 5 to facilitate the determination at 803. Where a trajectory 228 is found not to intersect with the one or more targeted zones T_{zone}, the method 800 can proceed to 804, and the reporter 207 can generate one or more data consistency reports 218 reporting status of the trajectory 228 (e.g., the data consistency report 218 can include conditional statement C₁). Where the trajectory 228 is determined to be intersecting with one or more of the targeted zones T_{zone}, the method 800 can proceed to 805.

At 805, the method 800 can comprise calculating (e.g., via the perforation checker 506), by the system 100, one or more perforation event 514 parameters, which can define the position and/or extent of a perforation event 514 along the trajectory 228. In accordance with one or more embodiments described herein, the perforation checker 506 can employ Equations 6-8 to calculate perforation event 514 parameters (e.g., Pₘₑₐₙ, Pₜₒₚ, P_{bottom}) from MD values extracted from the trajectory data (e.g., from deviation survey data 108).

At 806, the method 800 can comprise evaluating (e.g., via the conditional logic engine 508), by the system 100, the perforation events 514 based on conditional logic. In accordance with one or more embodiments described herein, the conditional logic engine 508 can employ Equations 9-15 to evaluate conditional statements C₂ to C₈.

At 808, the method 800 can comprise determining (e.g., via the conditional logic engine 508), by the system 800, whether there are one or more erroneous perforation portions 520 associated with the analyzed perforation event 514. In accordance with one more embodiments described herein, the conditional logic engine 508 can identify and/or classify one or more erroneous perforation portions 520 based on one or more of conditional statements defined in a library of perforation event 514 issues. For example, the library referenced at 808 can include conditional statements C₂ to C₇. For example, the library can include Table 1, which characterizes various circumstances in which an erroneous perforation portion 520 can be detected at 808. In various embodiments, the library can be stored in the computer readable storage media 204 and subject to periodic updates to account for newly defined perforation consistency issues. Where an erroneous perforation is not detected, the method 800 can proceed to 810. Where an erroneous perforation is detected, the method 800 can proceed to 812.

At 812, the method 800 can comprise determining (e.g., via correction engine 510), by the system 100, whether there is an associated correction operation that can be automatically implemented to remedy the occurrence of the erroneous perforation event 520. In accordance with one or more embodiments described herein, the correction engine 510 can reference library of perforation event 514 issues (e.g., exemplified by Table 2) to determine whether a defined correction operation is associated with one or more of the conditional statements classified by the conditional logic engine 508. For example, a table that correlates types of erroneous perforation events 520 to defined correction operations, such as Table 2, can be stored in the computer readable storage media 204 and referenced at 812. Where a defined correction operation is not associated with the detected erroneous perforation portion 520, the method 800 can proceed to 810. Where a defined correction operation is associated with the detected erroneous perforation portion 520, the method 800 can proceed to 814.

At 814, the method 800 can comprise executing (e.g., via the correction engine 510), by the system 100, the correction operation associated with the type of erroneous perforation portion 520 and identified at 812. For example, the correction engine 510 can adjust the MD_{perf.max} or MD_{perf.min} value to constrain the perforation event 514 to positions along the trajectory 228 and within the one or more targeted zones T_{zone}. For instance, one or more of the correction operations exemplified in FIG. 7 can be executed at 814.

At 810, the method 800 can comprise determining (e.g., via the perforation event analyzer 114), by the system 100, whether all the perforation events 514 for the given well have been analyzed. In one or more embodiments, a well can comprise multiple perforation events 514. Where a perforation event 514 of the well has not yet been analyzed, the method 800 can proceed back to feature 805 and features 806-814 can be repeated. Where all the perforation events 514 have been analyzed, the method 800 can proceed to 804.

At 804, the method 800 can comprise generating (e.g., via reporter 207), by the system 100, one or more data consistency reports 218. In accordance with various embodiments described herein, the one or more data consistency reports 218 can depict the status of the one or more perforation events 514. For example, the one or more data consistency reports 218 can include: identified trajectories 228 that fail to intersect with the targeted zones T_{zone}, detected erroneous perforation portions 520, conditional statements characterizing the state of one or more perforation events 514, and/or one or more correction operations implemented to remedy one or more erroneous perforation events 520. In various embodiments, the method 800 can be repeated for each well modeled by the subsurface reservoir simulation.

In an example execution of the system 100, the data assurance device 102 was employed to analyze a synthetic oilfield dataset characterizing 5500 wells. The dataset included input data inconsistency errors such as distorted well trajectories, wrong KB values, and/or erroneous perforation events. The well trajectory evaluator 112 and the perforation event analyzer 114 were deployed to quality check each component of the wells including well trajectory, KB value, and/or perforation with respect to targeted zones (e.g., subsurface geographical regions). For example, the data assurance device 102 was utilized to analyze data consistencies between grid horizons and well attributes (e.g., trajectory 228 and/or perforation events 514). For instance, the well trajectory evaluator 112 validated the KB values and well trajectories of the synthetic oilfield dataset against multiple data sources 104 in accordance with the various embodiments described herein. In doing so, the well trajectory evaluator 112 identified 173 errors (e.g., KB errors, trajectory errors, and/or TD errors) in a matter of minutes. Further, the perforation event analyzer 114 validated that the perforation events 514 defined by the synthetic oilfield dataset completed in the targeted zone T_{zone} (e.g., the perforation events 514 were confined to the targeted zone T_{zone}). Where erroneous perforation portions 520 were identified, the perforation event analyzer 114 gave an option to the user of the system 100 to approve one or more automatic correction operations.

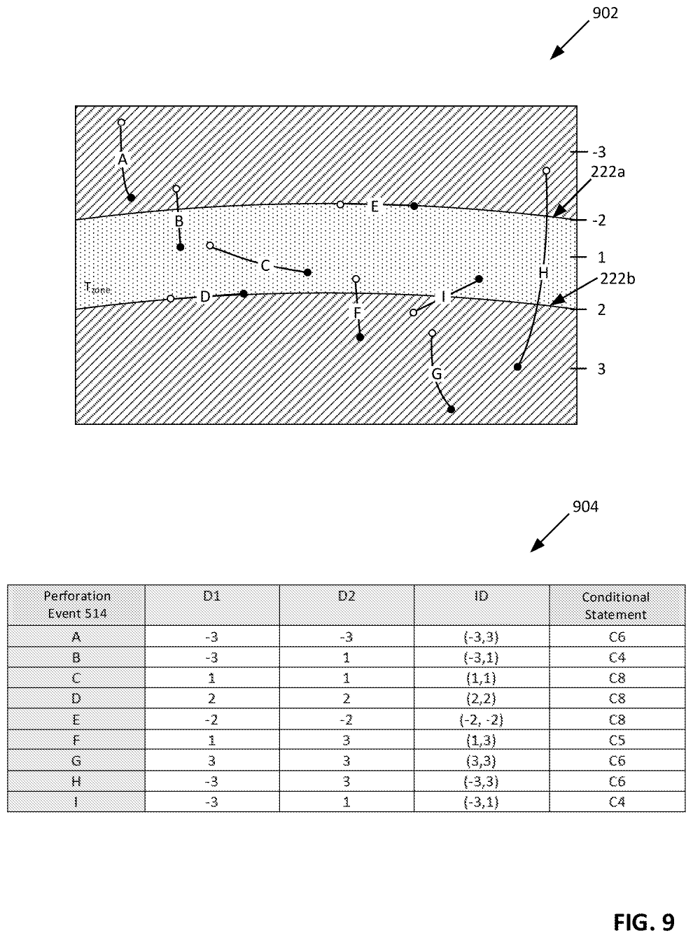

For example, FIG. 9 illustrates a plurality of perforation event 514 scenarios (e.g., A-I) that were detected by the perforation event analyzer 114 when analyzing the synthetic oilfield dataset. For example, FIG. 9 shows the perforation event 514 scenarios in relation to a portion of the simulation grid 902 comprising a targeted zone T_{zone}. Table 904 characterizes the various perforation event 514 scenarios shown in the simulation grid 902 with regards to the MD_{perf.min} (e.g., represented by white circles) and the MD_{perf.max} (e.g., represented by black circles), together constituting an identification metric, along with a correction operation that can be automatically executed to remedy erroneous perforation event portions 520 (e.g., with reference to Table 2). As shown in FIG. 9, MD values positioned within the targeted zone T_{zone} are labeled with a value of 1. MD values along the first grid horizon 222a are labeled with a value of −2. MD values positioned along the second grid horizon 222b are labeled with a value of 2. MD values positioned above the targeted zone T_{zone} are labelled with a value of −3. Also, MD values positioned below the targeted zone T_{zone} are labelled with a value of 3.

In this exemplary use case, the data assurance device 102 was able to evaluate the synthetic oilfield dataset 90% quicker than conventional techniques. Additionally, the data assurance device 102 was able to detect and automatically correct 100% of the trajectory and/or perforation errors introduced into the synthetic oilfield dataset.

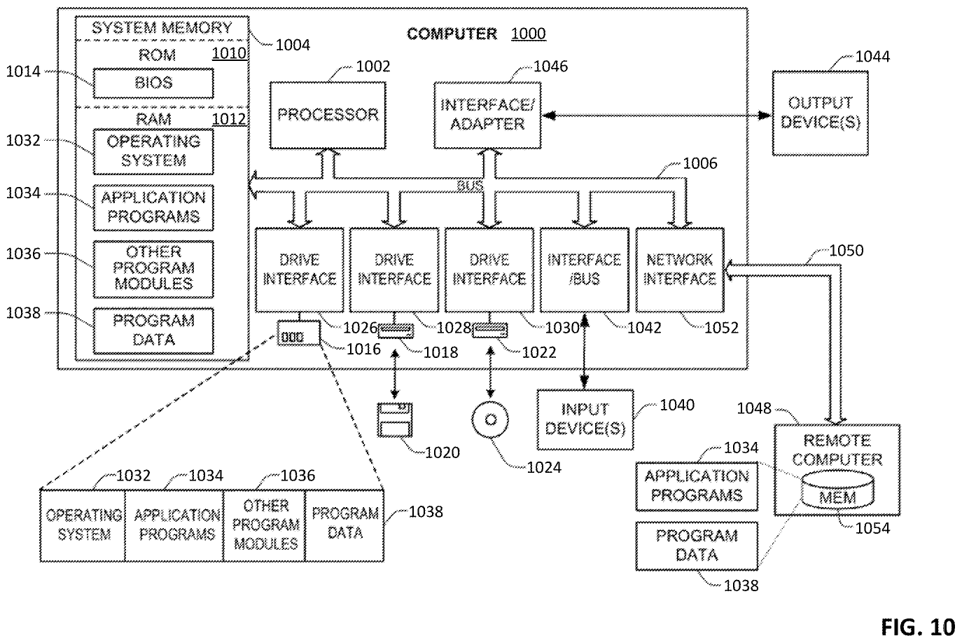

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 10. Furthermore, portions of the embodiments may be a computer program product on a computer-usable storage medium having computer readable program code on the medium. Any non-transitory, tangible storage media possessing structure may be utilized including, but not limited to, static and dynamic storage devices, hard disks, optical storage devices, and magnetic storage devices, but excludes any medium that is not eligible for patent protection under 35 U.S.C. § 101 (such as a propagating electrical or electromagnetic signal per se). As an example and not by way of limitation, a computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, where appropriate.

Certain embodiments have also been described herein with reference to block illustrations of methods, systems, and computer program products. It will be understood that blocks of the illustrations, and combinations of blocks in the illustrations, can be implemented by computer-executable instructions. These computer-executable instructions may be provided to one or more processor of a general purpose computer, special purpose computer, or other programmable data processing apparatus (or a combination of devices and circuits) to produce a machine, such that the instructions, which execute via the processor, implement the functions specified in the block or blocks.

These computer-executable instructions may also be stored in computer-readable memory that can direct a computer or other programmable data processing apparatus to function in a particular manner, such that the instructions stored in the computer-readable memory result in an article of manufacture including instructions which implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions specified in the flowchart block or blocks.

In this regard, FIG. 10 illustrates one example of a computer system 1000 that can be employed to execute one or more embodiments of the present disclosure. Computer system 1000 can be implemented on one or more general purpose networked computer systems, embedded computer systems, routers, switches, server devices, client devices, various intermediate devices/nodes or standalone computer systems. Additionally, computer system 1000 can be implemented on various mobile clients such as, for example, a personal digital assistant (PDA), laptop computer, pager, and the like, provided it includes sufficient processing capabilities.

Computer system 1000 includes processing unit 1002, system memory 1004, and system bus 1006 that couples various system components, including the system memory 1004, to processing unit 1002. Dual microprocessors and other multi-processor architectures also can be used as processing unit 1002. System bus 1006 may be any of several types of bus structure including a memory bus or memory controller, a peripheral bus, and a local bus using any of a variety of bus architectures. System memory 1004 includes read only memory (ROM) 1010 and random access memory (RAM) 1012. A basic input/output system (BIOS) 1014 can reside in ROM 1010 containing the basic routines that help to transfer information among elements within computer system 1000.

Computer system 1000 can include a hard disk drive 1016, magnetic disk drive 1018, e.g., to read from or write to removable disk 1020, and an optical disk drive 1022, e.g., for reading CD-ROM disk 1024 or to read from or write to other optical media. Hard disk drive 1016, magnetic disk drive 1018, and optical disk drive 1022 are connected to system bus 1006 by a hard disk drive interface 1026, a magnetic disk drive interface 1028, and an optical drive interface 1030, respectively. The drives and associated computer-readable media provide nonvolatile storage of data, data structures, and computer-executable instructions for computer system 1000. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and described herein.

A number of program modules may be stored in drives and RAM 1010, including operating system 1032, one or more application programs 1034, other program modules 1036, and program data 1038. In some examples, the application programs 1034 can include the simulation engine 110, well trajectory evaluator 112, and/or perforation event analyzer 114 and the program data 1038 can include the trajectories dataframes 216, difference dataframes 217, data consistency reports 218, and/or zone log 522. The application programs 1034 and program data 1038 can include functions and methods programmed to: (1) evaluation well trajectories modeled by a subsurface reservoir simulation based on data consistency between deviation survey data 108 from data sources 104 and detected trajectory distortions; and (2) analyze perforation events 514 modeled by the subsurface reservoir simulation and remedy one or more erroneous perforation portions 520, such as shown and described herein.

A user may enter commands and information into computer system 1000 through one or more input devices 1040, such as a pointing device (e.g., a mouse, touch screen), keyboard, microphone, joystick, game pad, scanner, and the like. For instance, the user can employ input device 1040 to edit or modify the KB tolerance, the trajectory tolerance, the DLS tolerance, and/or which zones are classified as targeted zones T_{zone}. These and other input devices 1040 are often connected to processing unit 1002 through a corresponding port interface 1042 that is coupled to the system bus, but may be connected by other interfaces, such as a parallel port, serial port, or universal serial bus (USB). One or more output devices 1044 (e.g., display, a monitor, printer, projector, or other type of displaying device) is also connected to system bus 1006 via interface 1046, such as a video adapter.

Computer system 1000 may operate in a networked environment using logical connections to one or more remote computers, such as remote computer 1048. Remote computer 1048 may be a workstation, computer system, router, peer device, or other common network node, and typically includes many or all the elements described relative to computer system 1000. The logical connections, schematically indicated at 1050, can include a local area network (LAN) and a wide area network (WAN). When used in a LAN networking environment, computer system 1000 can be connected to the local network through a network interface or adapter 1052. When used in a WAN networking environment, computer system 1000 can include a modem, or can be connected to a communications server on the LAN. The modem, which may be internal or external, can be connected to system bus 1006 via an appropriate port interface. In a networked environment, application programs 1034 or program data 1038 depicted relative to computer system 1000, or portions thereof, may be stored in a remote memory storage device 1054.

### Additional Embodiments

The present disclosure is also directed to the following exemplary embodiments:

Embodiment 1: A system, comprising: memory to store computer executable instructions; and one or more processors, operatively coupled to the memory, that execute the computer executable instructions to implement: a well trajectory evaluator configured to validate well trajectory data for a subsurface reservoir simulation model by comparing a difference between sets of deviation survey data to a defined trajectory tolerance; and a perforation event analyzer configured to validate well attribute data for the subsurface reservoir simulation model via conditional logic that analyzes the position of a perforation event along a well trajectory in relation to a targeted geographical zone.

Embodiment 2: The system of embodiment 1, wherein a first set of deviation survey data is supplied by a first data source, and wherein a second set of deviation survey data is supplied by a second data source.

Embodiment 3: The system of embodiments 1 or 2, further comprising: a dataframe generator configured to generate a first trajectories dataframe that defines the well trajectory by extracting a first set of parameters from the first set of deviation survey data, where the dataframe generator is further configured to generate a second trajectories dataframe that defines the well trajectory by extracting a second set of parameters from the second set of deviation survey data.

Embodiment 4: The system of any of embodiments 1-3, wherein the first set of parameters and the second set of parameters define three dimensional coordinates and measured depth of points where the well trajectory intersects grid horizons of the subsurface reservoir simulation model.

Embodiment 5: The system of any of embodiments 1-4, further comprising: a distortion analyzer configured to calculate a dogleg severity attribute for the well trajectory and compares the dogleg severity attribute to a defined tolerance to determine whether the well trajectory is distorted.

Embodiment 6: The system of any of embodiments 1-5, further comprising: a zone logger configured to label data points along the well trajectory based on a geological zone in which the data points are positioned; and an intersection checker configured to determine whether the well trajectory intersects the targeted geographical zone.

Embodiment 7: The system of any of embodiments 1-6, further comprising: a perforation checker configured to calculate a minimum measured depth and a maximum measured depth of the perforation event along the well trajectory; and a conditional logic engine configured to detect an erroneous perforation event portion and classify the erroneous perforation event portion as a type of perforation inconsistency based on the conditional logic.

Embodiment 8: The system of any of embodiments 1-7, further comprising: a correction engine configured to execute a predefined correction operation that remedies the erroneous perforation event portion, wherein the predefined correction operation adjusts the minimum measured depth of the perforation event, the maximum measured depth of the perforation event, or a combination thereof, and wherein the predefined correction operation is associated with the type of perforation inconsistency.

Embodiment 9: The system of any of embodiments 1-8, wherein the well trajectory data and the well attribute data is validated prior to generation of the subsurface reservoir simulation model.

Embodiment 10: A method, comprising: validating well trajectory data for a subsurface reservoir simulation model by comparing a difference between sets of deviation survey data to a defined trajectory tolerance; and validating well attribute data for the subsurface reservoir simulation model via conditional logic that analyzes the position of a perforation event along a well trajectory in relation to a targeted geographical zone.

Embodiment 11: The method of embodiment 10, further comprising: generating a first trajectories dataframe that defines the well trajectory by extracting a first set of parameters from the first set of deviation survey data; and generating a second trajectories dataframe that defines the well trajectory by extracting a second set of parameters from the second set of deviation survey data, wherein the first set of parameters and the second set of parameters define three dimensional coordinates and measured depth of points where the well trajectory intersects grid horizons of the subsurface reservoir simulation model.

Embodiment 12: The method of embodiment 10 or 11, further comprising: calculating a dogleg severity attribute for the well trajectory and compares the dogleg severity attribute to a defined tolerance to determine whether the well trajectory is distorted.

Embodiment 13: The method of any of embodiments 10-12, further comprising: labeling data points along the well trajectory based on a geological zone in which the data points are positioned; and determining whether the well trajectory intersects the targeted geographical zone.

Embodiment 14: The method of any of embodiments 10-13, further comprising: determining a minimum measured depth and a maximum measured depth of the perforation event along the well trajectory; and detecting an erroneous perforation event portion and classify the erroneous perforation event portion as a type of perforation inconsistency based on the conditional logic.

Embodiment 15: The method of any of embodiments 10-14, further comprising: executing a predefined correction operation that remedies the erroneous perforation event portion, wherein the predefined correction operation adjusts the minimum measured depth of the perforation event, the maximum measured depth of the perforation event, or a combination thereof, and wherein the predefined correction operation is associated with the type of perforation inconsistency.

Embodiment 16: A computer program product for performing a well trajectory data consistency check and a perforation event consistency check, the computer program product comprising a computer readable storage medium having computer executable instructions embodied therewith, the computer executable instructions executable by one or more processors to cause the one or more processors to: validate well trajectory data for a subsurface reservoir simulation model by comparing a difference between sets of deviation survey data to a defined trajectory tolerance; and validate well attribute data for the subsurface reservoir simulation model via conditional logic that analyzes the position of a perforation event along a well trajectory in relation to a targeted geographical zone.

Embodiment 17: The computer program product of embodiment 16, wherein the computer executable instructions further cause the one or more processors to: generate a first trajectories dataframe that defines the well trajectory by extracting a first set of parameters from the first set of deviation survey data; and generate a second trajectories dataframe that defines the well trajectory by extracting a second set of parameters from the second set of deviation survey data, wherein the first set of parameters and the second set of parameters define three dimensional coordinates and measured depth of points where the well trajectory intersects grid horizons of the subsurface reservoir simulation model.

Embodiment 18: The computer program product of embodiments 16 or 17, wherein the computer executable instructions further cause the one or more processors to: calculate a dogleg severity attribute for the well trajectory and compares the dogleg severity attribute to a defined tolerance to determine whether the well trajectory is distorted; label data points along the well trajectory based on a geological zone in which the data points are positioned; and determine whether the well trajectory intersects the targeted geographical zone.

Embodiment 19: The computer program product of any of embodiments 16-18, wherein the computer executable instructions further cause the one or more processors to: determine a minimum measured depth and a maximum measured depth of the perforation event along the well trajectory; and detect an erroneous perforation event portion and classify the erroneous perforation event portion as a type of perforation inconsistency based on the conditional logic.

Embodiment 20: The computer program product of any of embodiments 16-19, wherein the computer executable instructions further cause the one or more processors to: execute a predefined correction operation that remedies the erroneous perforation event portion, wherein the predefined correction operation adjusts the minimum measured depth of the perforation event, the maximum measured depth of the perforation event, or a combination thereof, and wherein the predefined correction operation is associated with the type of perforation inconsistency.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation are used herein merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, as used herein, the terms “coupled” or “coupled to” or “connected” or “connected to” or “attached” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

The invention claimed is:

1. A system, comprising:
memory to store computer executable instructions; and
one or more processors, operatively coupled to the memory, that execute the computer executable instructions to implement:
a well trajectory evaluator configured to validate well trajectory data for a subsurface reservoir simulation model by comparing a difference between sets of deviation survey data to a defined trajectory tolerance; and
a perforation event analyzer configured to validate well attribute data for the subsurface reservoir simulation model via conditional logic that analyzes the position of a perforation event along a well trajectory in relation to a targeted geographical zone.

2. The system of claim 1, wherein a first set of deviation survey data is supplied by a first data source, and wherein a second set of deviation survey data is supplied by a second data source.

3. The system of claim 2, further comprising:
a dataframe generator configured to generate a first trajectories dataframe that defines the well trajectory by extracting a first set of parameters from the first set of deviation survey data, where the dataframe generator is further configured to generate a second trajectories dataframe that defines the well trajectory by extracting a second set of parameters from the second set of deviation survey data.

4. The system of claim 3, wherein the first set of parameters and the second set of parameters define three dimensional coordinates and measured depth of points where the well trajectory intersects grid horizons of the subsurface reservoir simulation model.

5. The system of claim 1, further comprising:
a distortion analyzer configured to calculate a dogleg severity attribute for the well trajectory and compares the dogleg severity attribute to a defined tolerance to determine whether the well trajectory is distorted.

6. The system of claim 1, further comprising:
a zone logger configured to label data points along the well trajectory based on a geological zone in which the data points are positioned; and
an intersection checker configured to determine whether the well trajectory intersects the targeted geographical zone.

7. The system of claim 6, further comprising:
a perforation checker configured to calculate a minimum measured depth and a maximum measured depth of the perforation event along the well trajectory; and
a conditional logic engine configured to detect an erroneous perforation event portion and classify the erroneous perforation event portion as a type of perforation inconsistency based on the conditional logic.

8. The system of claim 7, further comprising:
a correction engine configured to execute a predefined correction operation that remedies the erroneous perforation event portion, wherein the predefined correction operation adjusts the minimum measured depth of the perforation event, the maximum measured depth of the perforation event, or a combination thereof, and wherein the predefined correction operation is associated with the type of perforation inconsistency.

9. The system of claim 1, wherein the well trajectory data and the well attribute data is validated prior to generation of the subsurface reservoir simulation model.

10. A method, comprising:
validating well trajectory data for a subsurface reservoir simulation model by comparing a difference between sets of deviation survey data to a defined trajectory tolerance; and
validating well attribute data for the subsurface reservoir simulation model via conditional logic that analyzes the position of a perforation event along a well trajectory in relation to a targeted geographical zone.

11. The method of claim 10, further comprising:
generating a first trajectories dataframe that defines the well trajectory by extracting a first set of parameters from the first set of deviation survey data; and
generating a second trajectories dataframe that defines the well trajectory by extracting a second set of parameters from the second set of deviation survey data, wherein the first set of parameters and the second set of parameters define three dimensional coordinates and measured depth of points where the well trajectory intersects grid horizons of the subsurface reservoir simulation model.

12. The method of claim 11, further comprising:
calculating a dogleg severity attribute for the well trajectory and compares the dogleg severity attribute to a defined tolerance to determine whether the well trajectory is distorted.

13. The method of claim 10, further comprising:
labeling data points along the well trajectory based on a geological zone in which the data points are positioned; and
determining whether the well trajectory intersects the targeted geographical zone.

14. The method of claim 13, further comprising:
determining a minimum measured depth and a maximum measured depth of the perforation event along the well trajectory; and
detecting an erroneous perforation event portion and classify the erroneous perforation event portion as a type of perforation inconsistency based on the conditional logic.

15. The method of claim 14, further comprising:
executing a predefined correction operation that remedies the erroneous perforation event portion, wherein the predefined correction operation adjusts the minimum measured depth of the perforation event, the maximum measured depth of the perforation event, or a combination thereof, and wherein the predefined correction operation is associated with the type of perforation inconsistency.

16. A computer program product for performing a well trajectory data consistency check and a perforation event consistency check, the computer program product comprising a computer readable storage medium having computer executable instructions embodied therewith, the computer executable instructions executable by one or more processors to cause the one or more processors to:
validate well trajectory data for a subsurface reservoir simulation model by comparing a difference between sets of deviation survey data to a defined trajectory tolerance; and
validate well attribute data for the subsurface reservoir simulation model via conditional logic that analyzes the position of a perforation event along a well trajectory in relation to a targeted geographical zone.

17. The computer program product of claim 16, wherein the computer executable instructions further cause the one or more processors to:
generate a first trajectories dataframe that defines the well trajectory by extracting a first set of parameters from the first set of deviation survey data; and
generate a second trajectories dataframe that defines the well trajectory by extracting a second set of parameters from the second set of deviation survey data, wherein the first set of parameters and the second set of parameters define three dimensional coordinates and measured depth of points where the well trajectory intersects grid horizons of the subsurface reservoir simulation model.

18. The computer program product of claim 17, wherein the computer executable instructions further cause the one or more processors to:
calculate a dogleg severity attribute for the well trajectory and compares the dogleg severity attribute to a defined tolerance to determine whether the well trajectory is distorted;
label data points along the well trajectory based on a geological zone in which the data points are positioned; and
determine whether the well trajectory intersects the targeted geographical zone.

19. The computer program product of claim 18, wherein the computer executable instructions further cause the one or more processors to:
determine a minimum measured depth and a maximum measured depth of the perforation event along the well trajectory; and
detect an erroneous perforation event portion and classify the erroneous perforation event portion as a type of perforation inconsistency based on the conditional logic.

20. The computer program product of claim 19, wherein the computer executable instructions further cause the one or more processors to:
execute a predefined correction operation that remedies the erroneous perforation event portion, wherein the predefined correction operation adjusts the minimum measured depth of the perforation event, the maximum measured depth of the perforation event, or a combination thereof, and wherein the predefined correction operation is associated with the type of perforation inconsistency.
